(19) United States
(12) Patent Application Publication
(10) Pub. No.: US 2012/0049951 A1
(43) Pub. Date: Mar. 1, 2012

(54) HIGH SPEED SWITCHED CAPACITOR REFERENCE BUFFER

(75) Inventors: Jagannathan Venkataraman, Bangalore (IN); Visvesvaraya A. Pentakota, Bangalore (IN); Ganesh Kiran, Bangalore (IN)

(73) Assignee: TEXAS INSTRUMENTS INCORPORATED, Dallas, TX (US)

(21) Appl. No.: 12/901,877

(22) Filed: Oct. 11, 2010

(30) Foreign Application Priority Data
Aug. 31, 2010 (IN) 2528/CHE/2010

(51) Int. Cl. H03F 1/00

(52) U.S. Cl. 330/112

(57) ABSTRACT

Conventional single-ended and differential reference buffers used for switched capacitor loads (such as sample-and-hold circuits for analog-to-digital converters) often have errors due to “memory” and are current source limited. Here, however, single-ended and differential reference buffers are provided, which include low bandwidth switched capacitor feedback loops to limit noise from the feedback loop and decouple internal bias nodes to avoid memory issues. Additionally, the differential reference buffers shown include flipped voltage followers that can sink/source large currents, which are not current source limited, and that can be underdamped so as to obtain a two pole settling response to reduce power consumption.

### CROSS-REFERENCE TO RELATED APPLICATIONS

This application claims priority from Indian Patent Application 2528/CHE/2010, filed Aug. 31, 2010, which is hereby incorporated by reference for all purposes.

### TECHNICAL FIELD

The invention relates generally to buffers and, more particularly, to buffers used to drive switched capacitor loads.

### BACKGROUND

Referring to FIG. 1 of the drawings, the reference numeral 100 generally designates a conventional input circuit for an analog-to-digital converter (ADC). Circuit 100 generally comprises a buffer 102-1 and sample-and-hold (S/H) circuit 104. Here, buffer 102-1 is little more than a non-inverting amplifier having an amplifier 106-1 and resistor network R1 and R2 that amplifies input signal IN. This amplified input signal (which is a reference signal) is applied to the S/H circuit 104, where the voltage level of the amplified input signal is applied capacitor CS during a hold phase (when switch SH is close) and where voltage V2 is sampled during a sample phase (when switch SS is closed and voltage V2 is applied to capacitor CS). Here, amplifier 106-1 directly drives the load, which means that the amplifier 106-1 must include a predetermined bandwidth to meet settling requirements, that amplifier 106-1 consumes a large amount of power, and that the buffer 102-1 is noisy.

To assist in alleviating some of the problems associated with input circuit 100, an alternative input circuit 200 (of FIG. 2) can be employed. In circuit 200, source follower (NMOS transistor Q2 and current source 110) are employed outside of the feedback loop for amplifier 106-1, and a “replica arm” or feedback circuit (NMOS transistor Q1 and current source 108) are employed within the feedback loop of amplifier 106-1. Additionally, an input capacitor CIN is coupled to the output terminal of amplifier 106-1. Here, the bandwidth and noise of the feedback loop of amplifier 106-1 are very low. However, due to the large gate-source capacitance of transistor Q2, glitches (which occur when capacitor CS is coupled to the source transistor Q2) cause the low bandwidth feedback loop of amplifier 106-1 to slowly adjust for the glitch. Essentially, the voltage on the gate of transistor Q2 (and, consequently, the voltage provided at the output OUT) has a “memory,” which can cause errors.

Turning to FIG. 3, another alternative buffer 102-3 (which can accommodate differential signals) can be seen. Buffer 102-3 generally comprises a positive buffer 302 and a negative buffer 304. Positive buffer 302 generally comprises an input stage (amplifier 106-2, capacitors C1 and C2, resistor R3, and switches SP1 and SP2) and an output stage (PMOS transistors Q3 through Q6), and positive buffer 302 receives a bias voltage PBIAS. Negative buffer 304 generally comprises an input stage (amplifier 106-3, capacitors C3 and C4, resistor R4, and switches SM1 and SM2) and an output stage (PMOS transistors Q7 through Q10), and negative buffer 304 receives a bias voltage NBIAS. In operation, the output stages of positive buffer 302 and negative buffer 304 (which are generally mirror images of one another) operate as PMOS and NMOS source followers (respectively). As a result of this configuration, the PMOS follower sources current for downstream ADC, while the NMOS follower sinks current for the downstream ADC, so that the upper limit current capability is current source limited. Additionally, since the output stages of buffers 302 and 304 operate as source followers, these output stages tend to have a single pole settling response, so that there is relationship between settling time and power consumption.

Therefore, there is a need for single-ended and differential buffers with improved performance.

### SUMMARY

A preferred embodiment of the present invention, accordingly, provides an apparatus. The apparatus comprises a first input stage that receives a first portion of a differential input signal; a first output stage including: a first flipped voltage follower that is coupled to the first input stage and that provides a first output signal, and wherein the first flipped voltage follower receives a first bias signal; a first feedback circuit that is coupled to the first flipped voltage follower and the first input stage, wherein the first feedback circuit receives the first bias signal, and wherein the first feedback circuit provides a feedback signal to the first input stage; a second input stage that receives a second portion of the differential input signal; and a second output stage including: a second flipped voltage follower that is coupled to the second input stage and that provides a second output signal, and wherein the first flipped voltage follower receives a second bias signal; and a second feedback circuit that is coupled to the second flipped voltage follower and the second input stage, wherein the second feedback circuit receives the second bias signal, and wherein the first feedback circuit provides a second feedback signal to the second input stage.

In accordance with a preferred embodiment of the present invention, each of the first and second input stages further comprises: an amplifier that is coupled to one of the first and second feedback circuits; and a switched capacitor network that is coupled to the amplifier, one of the first and second feedback circuits, and one of the first and second flipped voltage followers, wherein the switched capacitor network is controlled by a sample-and-hold signal.

In accordance with a preferred embodiment of the present invention, the first feedback circuit further comprises: a PMOS transistor that receives the first bias signal at its gate; a first NMOS transistor that is coupled to the drain of the PMOS transistor at its drain and that is coupled to the first input stage at its gate and its source; a second NMOS transistor that is coupled to the source of the first NMOS transistor at its drain and that is coupled to the drain of the PMOS transistor at its gate; and a capacitor that is coupled to the drain of the PMOS transistor.

In accordance with a preferred embodiment of the present invention, the PMOS transistor further comprises a first PMOS transistor, and wherein the capacitor further comprises a first capacitor, and wherein the first flipped voltage follower further comprises: a second PMOS transistor that receives the first bias signal at its gate; a third NMOS transistor that is coupled to the first input stage at its gate and that is coupled to the drain of the second PMOS transistor at its drain; a fourth NMOS transistor that is coupled to the source of the third NMOS transistor at its drain and that is coupled to the drain of the second PMOS transistor at its gate; and a second capacitor that is coupled to the drain of the second PMOS transistor.

In accordance with a preferred embodiment of the present invention, the second feedback circuit further comprises: an NMOS transistor that receives the second bias signal at its gate; a first PMOS transistor that is coupled to the drain of the NMOS transistor at its drain and that is coupled to the second input stage at its gate and its source; a second PMOS transistor that is coupled to the source of the first PMOS transistor at its drain and that is coupled to the drain of the NMOS transistor at its gate; and a capacitor that is coupled to the drain of the NMOS transistor.

In accordance with a preferred embodiment of the present invention, the NMOS transistor further comprises a first NMOS transistor, and wherein the capacitor further comprises a first capacitor, and wherein the second flipped voltage follower further comprises: a second NMOS transistor that receives the second bias signal at its gate; a third PMOS transistor that is coupled to the second input stage at its gate and that is coupled to the drain of the second NMOS transistor at its drain; a fourth PMOS transistor that is coupled to the source of the third PMOS transistor at its drain and that is coupled to the drain of the second NMOS transistor at its gate; and a second capacitor that is coupled to the drain of the second NMOS transistor.

In accordance with a preferred embodiment of the present invention, an apparatus is provided. The apparatus comprises a first input stage including: a first amplifier having a first input terminal, a second input terminal, and an output terminal, wherein the first input terminal of the first amplifier receives a negative portion of a differential input signal; and a first switched capacitor network that is coupled to the output terminal of the first amplifier, wherein the switched capacitor network is controlled by a sample-and-hold signal; a first output stage including: a first flipped voltage follower that is coupled to the first switched capacitor and that provides a first output signal, and wherein the first flipped voltage follower receives a first bias signal; and a first feedback circuit that is coupled to the first flipped voltage follower and the first switched capacitor network, wherein the first feedback circuit receives the first bias signal, and wherein the first feedback circuit provides a feedback signal to the second input terminal of the first amplifier; a second input stage including: a second amplifier having a first input terminal, a second input terminal, and an output terminal, wherein the first input terminal of the second amplifier receives a positive portion of a differential input signal; and a second switched capacitor network that is coupled to the output terminal of the second amplifier, wherein the switched capacitor network is controlled by the sample-and-hold signal; and a second output stage including: a second flipped voltage follower that is coupled to the second switched capacitor and that provides a second output signal, and wherein the second flipped voltage follower receives a second bias signal; and a second feedback circuit that is coupled to the second flipped voltage follower and the second switched capacitor network, wherein the second feedback circuit receives the second bias signal, and wherein the second feedback circuit provides a second feedback signal to the second input terminal of the second amplifier.

In accordance with a preferred embodiment of the present invention, the each of the first and second switched capacitor networks further comprises: a first switch that is closed during a sample period of the sample-and-hold signal; a second switch that is coupled to the first switch and that is coupled to one of the first and second output stages, wherein the second switch is closed during a hold period of the sample-and-hold signal; a first capacitor that is coupled to a node between the first and second switches; and a second capacitor that is coupled to the second switch.

In accordance with a preferred embodiment of the present invention, the first feedback circuit further comprises: a PMOS transistor that receives the first bias signal at its gate; a first NMOS transistor that is coupled to the drain of the PMOS transistor at its drain and that is coupled to the first switch network at its gate and its source; a second NMOS transistor that is coupled to the source of the first NMOS transistor at its drain and that is coupled to the drain of the PMOS transistor at its gate; and a capacitor that is coupled to the drain of the PMOS transistor.

In accordance with a preferred embodiment of the present invention, PMOS transistor further comprises a first PMOS transistor, and wherein the capacitor further comprises a first capacitor, and wherein the first flipped voltage follower further comprises: a second PMOS transistor that receives the first bias signal at its gate; a third NMOS transistor that is coupled to the first switched at its gate and that is coupled to the drain of the second PMOS transistor at its drain; a fourth NMOS transistor that is coupled to the source of the third NMOS transistor at its drain and that is coupled to the drain of the second PMOS transistor at its gate; and a second capacitor that is coupled to the drain of the second PMOS transistor.

In accordance with a preferred embodiment of the present invention, the second feedback circuit further comprises: an NMOS transistor that receives the second bias signal at its gate; a first PMOS transistor that is coupled to the drain of the NMOS transistor at its drain and that is coupled to the second input stage at its gate and its source; a second PMOS transistor that is coupled to the source of the first PMOS transistor at its drain and that is coupled to the drain of the NMOS transistor at its gate; and a capacitor that is coupled to the drain of the NMOS transistor.

In accordance with a preferred embodiment of the present invention, the NMOS transistor further comprises a first PMOS transistor, and wherein the capacitor further comprises a first capacitor, and wherein the second flipped voltage follower further comprises: a second NMOS transistor that receives the second bias signal at its gate; a third PMOS transistor that is coupled to the second input stage at its gate and that is coupled to the drain of the second NMOS transistor at its drain; a fourth PMOS transistor that is coupled to the source of the third PMOS transistor at its drain and that is coupled to the drain of the second NMOS transistor at its gate; and a second capacitor that is coupled to the drain of the second NMOS transistor.

In accordance with a preferred embodiment of the present invention, an apparatus comprising: an amplifier having a first input terminal, a second input terminal, and an output terminal, wherein the first input terminal receives an input signal; a switched capacitor network having: a first switch that is coupled to the output terminal of the amplifier, wherein the first switch is closed during a hold period and is open during a sample period; a first capacitor that is coupled to the first switch; and a second switch that is coupled to the first switch, wherein the second switch is closed during a sample period and is open during a hold period; an output stage that is coupled to the second switch; and a resistor network that is coupled between the output stage and the second input terminal of the amplifier.

In accordance with a preferred embodiment of the present invention, the output stage further comprises: a first transistor that is coupled to the second switch at its control terminal and the resistor network at its first passive terminal; a second transistor that is coupled to the second switch at its control terminal; a first current source that is coupled to the first passive terminal of the first transistor; and a second current source that is coupled to a first passive terminal of the second transistor.

In accordance with a preferred embodiment of the present invention, the first and second transistors further comprise first and second NMOS transistors that coupled to the first and second current sources at their respective sources.

In accordance with a preferred embodiment of the present invention, the resistor network further comprises: a first resistor that is coupled between source of the first NMOS transistor and the second output terminal of the amplifier; and a second resistor that is coupled between the second output terminal of the amplifier and ground.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 and 2 are an examples of conventional input circuits;

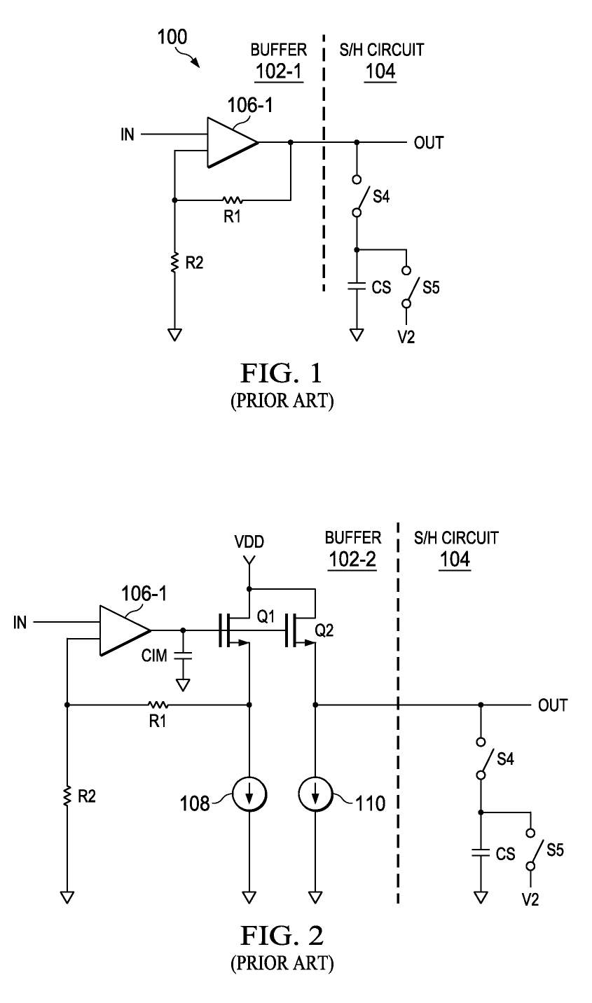

FIG. 3 is an example of a conventional differential buffer;

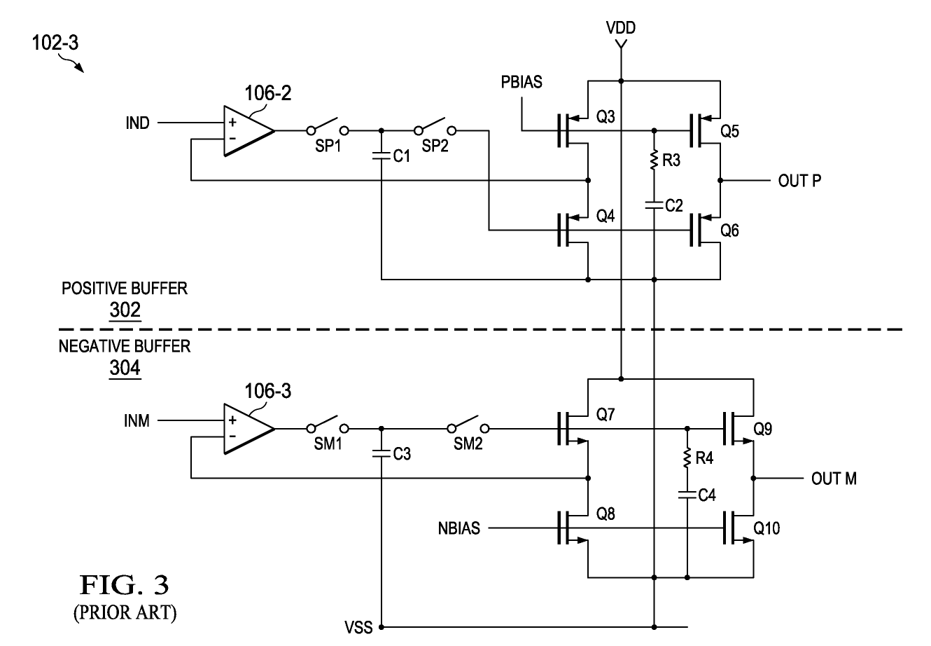

FIG. 4 is an example of a single-ended input circuit in accordance with a preferred embodiment of the present invention; and

FIG. 5 is an example of a differential buffer in accordance with a preferred embodiment of the present invention.

### DETAILED DESCRIPTION

Refer now to the drawings wherein depicted elements are, for the sake of clarity, not necessarily shown to scale and wherein like or similar elements are designated by the same reference numeral through the several views.

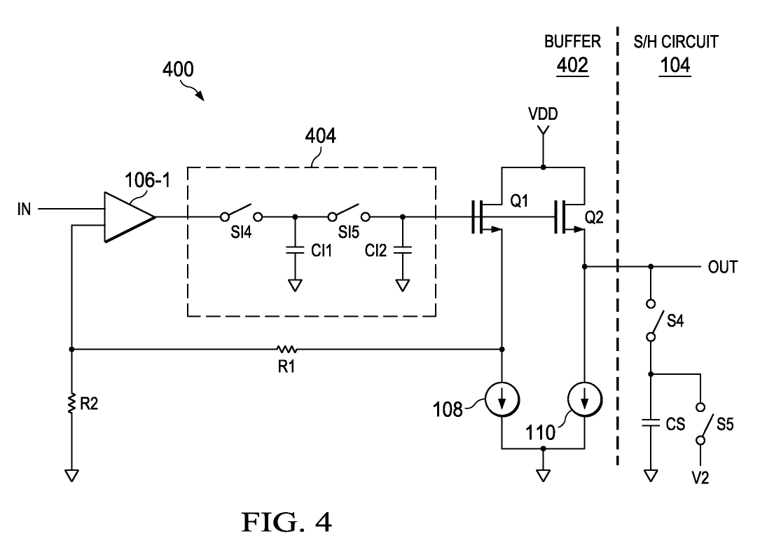

Turning to FIG. 4, an input circuit 400 in accordance with a preferred embodiment of the present invention can be seen. Circuit 400 generally comprises a sample-and-hold (S/H) circuit 102 and buffer 402. Buffer 402 has the same general construction as buffer 102-2 except that buffer 400 includes a switched capacitor network 404 between the output terminal of amplifier 106-1 and the gate of transistor Q1. This switched capacitor network 402 generally comprises switches SIS and SIH and capacitors CI1 and CI2.

In operation, the switched capacitor network 402 is able to set the bias voltage for the output stage (transistors Q1 and Q2 and current source 108 and 110) by opening and closing the feedback loop of amplifier 106-1 during the sample and hold cycle. During a hold phase (when a glitch is applied to the voltage at the gate of transistor Q2), the feedback loop for amplifier 106-1 is open because switch SIS is open. At the end of the hold phase, the voltage at the source of transistor Q2 would have settled, allowing the voltage at the gate of transistor Q2 to return to its normal bias voltage. Thus, when switch SIS closes and switch SIH opens during the sample phase, the (now closed) feedback loop for amplifier 106-1 does not “see” the glitch, which generally eliminates the memory present in buffer 102-2. Additionally, because noise from the switch capacitor network 402 and amplifier 106-1 are attenuated due to the ratio of the size of capacitor C1 to the size of capacitor C2 (which is about 1000), the output stage (transistor Q2 and current source 110) become the most significant source of noise.

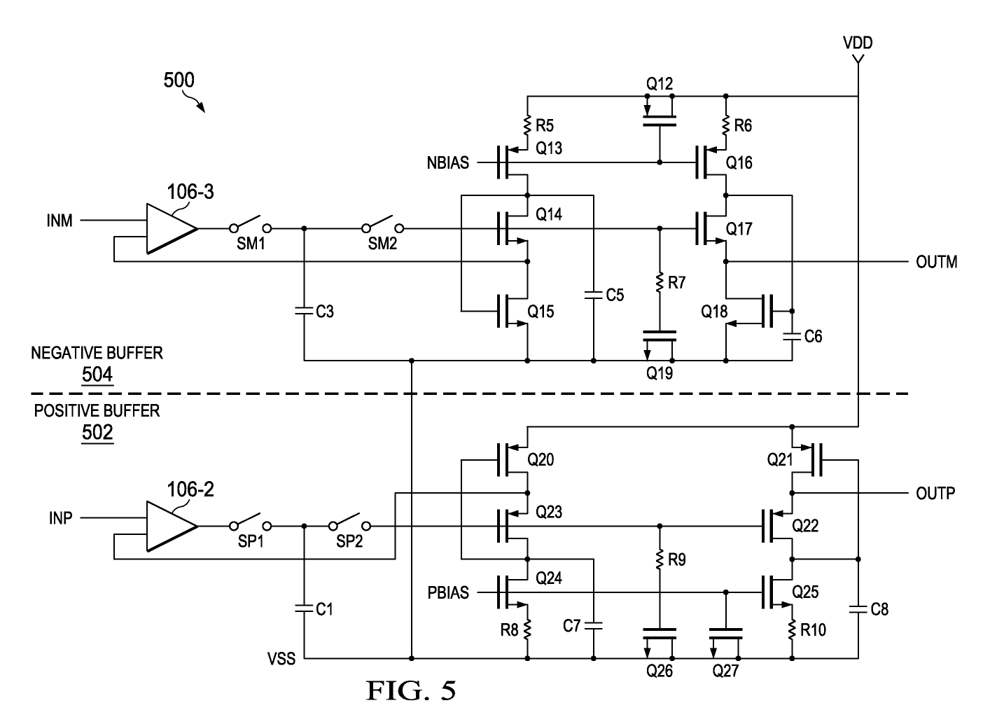

Turning now to FIG. 5, a differential buffer 500 in accordance with a preferred embodiment of the present invention can be seen. Similar to buffer 102-3, buffer 500 includes a positive buffer 502 and negative buffer 504. Each of the positive and negative buffers 502 and 504 has the same general construction as positive and negative buffers 302 and 304 (respectively) except that the output stages of buffers 502 and 504 are “flipped.”

Looking to the positive buffer 502 (for example), the output stage of buffer 502 includes a feedback circuit and a flipped voltage follower. The flipped voltage follower of buffer 502 generally comprises PMOS transistors Q21 and Q22, NMOS transistor Q25, resistor R10, capacitor C8, and capacitor-connected transistor Q27, and flipped voltage follower of buffer 502 operates to source large currents compared to conventional source followers (such as the source follower of buffer 302) in order to directly drive a load such that the current capability is not current source limited. The feedback circuit of buffer 502 (which is a replica of the flipped voltage follower of buffer 502) generally comprises PMOS transistors Q20 and Q23, NMOS transistor Q24, resistor R8, and capacitor C7 and is located in the feedback loop of the input stage (amplifier 106-2, switches SP1 and SP2, resistors R9, and capacitor-connected transistor Q26). The feedback loop (formed of the feedback circuit and the input stage and similar to buffer 402), is switched capacitor with a very low bandwidth, which generally limits the noise from the loop and which decouples to the internal bias node to generally avoid the memory issue that is seen in the continuous loops. The flipped voltage follower of buffer 502 can also be underdamped so as to obtain a two pole settling response to reduce power consumption.

Negative buffer 504 has a similar construction of (but is generally a mirror image of) buffer 502. Namely, the flipped voltage follower of buffer 504 generally comprises PMOS transistors Q13 and Q14, PMOS transistor Q15, resistor R5, capacitor C5, and capacitor-connected transistor Q12, and flipped voltage follower of buffer 504 operates to sink large currents compared to conventional source followers (such as the source follower of buffer 304) in order to directly drive a load. The feedback circuit of buffer 504 (which is a replica of the flipped voltage follower) generally comprises PMOS transistors Q16 and Q17, NMOS transistor Q18, resistor R6, and capacitor C6 and is located in the feedback loop of the input stage (amplifier 106-3, switches SM1 and SM2, resistors R7, and capacitor-connected transistor Q19). The feedback loop (formed of the feedback circuit and the input stage and similar to buffer 402), is, too, switched capacitor with a very low bandwidth, which generally limits the noise from the loop and which decouples to the internal bias node to generally avoid the memory issue that is seen in the continuous loops. The flipped voltage follower of buffer 504 can also be underdamped so as to obtain a two pole settling response to reduce power consumption.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a first input stage that receives a first portion of a differential input signal;
a first output stage including:
a first flipped voltage follower that is coupled to the first input stage and that provides a first output signal, and wherein the first flipped voltage follower receives a first bias signal;
a first feedback circuit that is coupled to the first flipped voltage follower and the first input stage, wherein the first feedback circuit receives the first bias signal, and wherein the first feedback circuit provides a feedback signal to the first input stage;
a second input stage that receives a second portion of the differential input signal; and
a second output stage including:
a second flipped voltage follower that is coupled to the second input stage and that provides a second output signal, and wherein the first flipped voltage follower receives a second bias signal; and
a second feedback circuit that is coupled to the second flipped voltage follower and the second input stage, wherein the second feedback circuit receives the second bias signal, and wherein the first feedback circuit provides a second feedback signal to the second input stage.

2. The apparatus of claim 1, wherein each of the first and second input stages further comprises:
an amplifier that is coupled to one of the first and second feedback circuits; and
a switched capacitor network that is coupled to the amplifier, one of the first and second feedback circuits, and one of the first and second flipped voltage followers, wherein the switched capacitor network is controlled by a sample-and-hold signal.

3. The apparatus of claim 1, wherein the first feedback circuit further comprises:
a PMOS transistor that receives the first bias signal at its gate;
a first NMOS transistor that is coupled to the drain of the PMOS transistor at its drain and that is coupled to the first input stage at its gate and its source;
a second NMOS transistor that is coupled to the source of the first NMOS transistor at its drain and that is coupled to the drain of the PMOS transistor at its gate; and
a capacitor that is coupled to the drain of the PMOS transistor.

4. The apparatus of claim 3, wherein the PMOS transistor further comprises a first PMOS transistor, and wherein the capacitor further comprises a first capacitor, and wherein the first flipped voltage follower further comprises:
a second PMOS transistor that receives the first bias signal at its gate;
a third NMOS transistor that is coupled to the first input stage at its gate and that is coupled to the drain of the second PMOS transistor at its drain;
a fourth NMOS transistor that is coupled to the source of the third NMOS transistor at its drain and that is coupled to the drain of the second PMOS transistor at its gate; and
a second capacitor that is coupled to the drain of the second PMOS transistor.

5. The apparatus of claim 1, wherein the second feedback circuit further comprises:
an NMOS transistor that receives the second bias signal at its gate;
a first PMOS transistor that is coupled to the drain of the NMOS transistor at its drain and that is coupled to the second input stage at its gate and its source;
a second PMOS transistor that is coupled to the source of the first PMOS transistor at its drain and that is coupled to the drain of the NMOS transistor at its gate; and
a capacitor that is coupled to the drain of the NMOS transistor.

6. The apparatus of claim 5, wherein the NMOS transistor further comprises a first NMOS transistor, and wherein the capacitor further comprises a first capacitor, and wherein the second flipped voltage follower further comprises:
a second NMOS transistor that receives the second bias signal at its gate;
a third PMOS transistor that is coupled to the second input stage at its gate and that is coupled to the drain of the second NMOS transistor at its drain;
a fourth PMOS transistor that is coupled to the source of the third PMOS transistor at its drain and that is coupled to the drain of the second NMOS transistor at its gate; and
a second capacitor that is coupled to the drain of the second NMOS transistor.

7. An apparatus comprising:
a first input stage including:
a first amplifier having a first input terminal, a second input terminal, and an output terminal, wherein the first input terminal of the first amplifier receives a negative portion of a differential input signal; and
a first switched capacitor network that is coupled to the output terminal of the first amplifier, wherein the switched capacitor network is controlled by a sample-and-hold signal;
a first output stage including:
a first flipped voltage follower that is coupled to the first switched capacitor and that provides a first output signal, and wherein the first flipped voltage follower receives a first bias signal; and
a first feedback circuit that is coupled to the first flipped voltage follower and the first switched capacitor network, wherein the first feedback circuit receives the first bias signal, and wherein the first feedback circuit provides a feedback signal to the second input terminal of the first amplifier;
a second input stage including:
a second amplifier having a first input terminal, a second input terminal, and an output terminal, wherein the first input terminal of the second amplifier receives a positive portion of a differential input signal; and
a second switched capacitor network that is coupled to the output terminal of the second amplifier, wherein the switched capacitor network is controlled by the sample-and-hold signal; and
a second output stage including:
a second flipped voltage follower that is coupled to the second switched capacitor and that provides a second output signal, and wherein the second flipped voltage follower receives a second bias signal; and
a second feedback circuit that is coupled to the second flipped voltage follower and the second switched capacitor network, wherein the second feedback circuit receives the second bias signal, and wherein the second feedback circuit provides a second feedback signal to the second input terminal of the second amplifier.

8. The apparatus of claim 7, wherein the each of the first and second switched capacitor networks further comprises:
a first switch that is closed during a sample period of the sample-and-hold signal;
a second switch that is coupled to the first switch and that is coupled to one of the first and second output stages, wherein the second switch is closed during a hold period of the sample-and-hold signal;
a first capacitor that is coupled to a node between the first and second switches; and
a second capacitor that is coupled to the second switch.

9. The apparatus of claim 7, wherein the first feedback circuit further comprises:
a PMOS transistor that receives the first bias signal at its gate;
a first NMOS transistor that is coupled to the drain of the PMOS transistor at its drain and that is coupled to the first switch network at its gate and its source;
a second NMOS transistor that is coupled to the source of the first NMOS transistor at its drain and that is coupled to the drain of the PMOS transistor at its gate; and
a capacitor that is coupled to the drain of the PMOS transistor.

10. The apparatus of claim 9, wherein the PMOS transistor further comprises a first PMOS transistor, and wherein the capacitor further comprises a first capacitor, and wherein the first flipped voltage follower further comprises:
a second PMOS transistor that receives the first bias signal at its gate;
a third NMOS transistor that is coupled to the first switched at its gate and that is coupled to the drain of the second PMOS transistor at its drain;
a fourth NMOS transistor that is coupled to the source of the third NMOS transistor at its drain and that is coupled to the drain of the second PMOS transistor at its gate; and
a second capacitor that is coupled to the drain of the second PMOS transistor.

11. The apparatus of claim 7, wherein the second feedback circuit further comprises:
an NMOS transistor that receives the second bias signal at its gate;
a first PMOS transistor that is coupled to the drain of the NMOS transistor at its drain and that is coupled to the second input stage at its gate and its source;
a second PMOS transistor that is coupled to the source of the first PMOS transistor at its drain and that is coupled to the drain of the NMOS transistor at its gate; and
a capacitor that is coupled to the drain of the NMOS transistor.

12. The apparatus of claim 11, wherein the NMOS transistor further comprises a first PMOS transistor, and wherein the capacitor further comprises a first capacitor, and wherein the second flipped voltage follower further comprises:
a second NMOS transistor that receives the second bias signal at its gate;
a third PMOS transistor that is coupled to the second input stage at its gate and that is coupled to the drain of the second NMOS transistor at its drain;
a fourth PMOS transistor that is coupled to the source of the third PMOS transistor at its drain and that is coupled to the drain of the second NMOS transistor at its gate; and
a second capacitor that is coupled to the drain of the second NMOS transistor.

13. An apparatus comprising:
an amplifier having a first input terminal, a second input terminal, and an output terminal, wherein the first input terminal receives an input signal;
a switched capacitor network having:
a first switch that is coupled to the output terminal of the amplifier, wherein the first switch is closed during a hold period and is open during a sample period;
a first capacitor that is coupled to the first switch; and
a second switch that is coupled to the first switch, wherein the second switch is closed during a sample period and is open during a hold period;
an output stage that is coupled to the second switch; and
a resistor network that is coupled between the output stage and the second input terminal of the amplifier.

14. The apparatus of claim 13, wherein the output stage further comprises:
a first transistor that is coupled to the second switch at its control terminal and the resistor network at its first passive terminal;
a second transistor that is coupled to the second switch at its control terminal;
a first current source that is coupled to the first passive terminal of the first transistor; and
a second current source that is coupled to a first passive terminal of the second transistor.

15. The apparatus of claim 14, wherein the first and second transistors further comprise first and second NMOS transistors that coupled to the first and second current sources at their respective sources.

16. The apparatus of claim 15, wherein the resistor network further comprises:
a first resistor that is coupled between source of the first NMOS transistor and the second output terminal of the amplifier; and
a second resistor that is coupled between the second output terminal of the amplifier and ground.
